(19) United States
(12) Patent Application Publication
(10) Pub. No.: US 2012/0032267 A1
(43) Pub. Date: Feb. 9, 2012

(54) DEVICE AND METHOD FOR UNIFORM STI RECESS

(75) Inventors: KANGGUO CHENG, Guilderland, NY (US); Bruce B. Doris, Brewster, NY (US); Ali Khakifirooz, Slingerlands, NY (US); Ghavam G. Shahidi, Pound Ridge, NY (US)

(73) Assignee: INTERNATIONAL BUSINESS MACHINES CORPORATION, Armonk, NY (US)

(21) Appl. No.: 12/851,966

(22) Filed: Aug. 6, 2010

(51) Int. Cl. H01L 29/06; H01L 21/302

(52) U.S. Cl. 257/368; 438/423; 257/E21.214; 257/E29.018

(57) ABSTRACT

A semiconductor device and method for forming the semiconductor device include forming structures in a semiconductor substrate. The structures have two or more different spacings between them. A dielectric material is deposited in the spacings. Ion species are implanted to a depth in the dielectric material to change an etch rate of the dielectric material down to the depth. The dielectric material having the ion species is etched selective to the dielectric material below the depth such that a substantially uniform depth in the dielectric material is created across the at least two spacings.

### BACKGROUND

1. Technical Field

The present invention relates to semiconductor devices and processing, and more particularly to devices and methods with uniformly recessed shallow trench isolation regions.

2. Description of the Related Art

Shallow trench isolation (STI) refers to the formation of a dielectric material in and/or on a semiconductor substrate to isolate devices formed in the substrate. STI prevents or reduces leakage currents and any other electrical interactions between devices. Many processes require that the STI be recessed to lower a top surface before further processing can take place. In devices where fins or other substrate structures are formed, recessing the STI becomes challenging as the recess level is dependent on the density of the structures and the amount of space between them.

In one example, bulk fin field effect transistors (FETs) employ a fin formed from substrate material. These fins may be formed with different densities on a given substrate. An STI recess is needed to form isolation. It is difficult to uniformly recess the STI due to loading effects of conventional etch processes (e.g., areas with tight pitch are recessed deeper than an area with relaxed pitch).

Referring to FIG. 1, a conventional semiconductor device 10 includes a bulk silicon substrate 12 which is etched back using a patterned cap layer 18 to form fins 16. The fins are formed with different pitches. Region 20 includes a relaxed pitch area where the fins 16 are spread out more than in a tight-pitch area of region 22. An STI dielectric 14 is deposited and etched back for device processing. An STI recess depth variation results in undesired fin height variation (e.g., H1 versus H2) and thus device variation occurs. A non-uniform STI recess results due to loading effects of the etching process such that region 22 (with tight pitch) is recessed deeper than the region 20 (with relaxed pitch).

### SUMMARY

A semiconductor device and method for forming the semiconductor device include forming structures in a semiconductor substrate. The structures have two or more different spacings between them. A dielectric material is deposited in the spacings. Ion species are implanted to a depth in the dielectric material to change an etch rate of the dielectric material down to the depth. The dielectric material having the ion species is etched selective to the dielectric material below the depth such that a substantially uniform depth in the dielectric material is created across the at least two spacings.

Another method for forming a semiconductor device includes forming fin structures in a semiconductor substrate, the structures having regions with at least two different spacings between the fins; depositing a dielectric material in the at least two different spacings; implanting an inert ion species to a depth in the dielectric material and in the fin structures to change an etch rate of the dielectric material down to the depth; and etching the dielectric material having the ion species selective to the dielectric material below the depth to form a shallow trench isolation region having a substantially uniform depth in the dielectric material created across the at least two spacings.

A semiconductor device includes a plurality of fin structures having at least two different spacings integrally formed in a semiconductor substrate. A shallow trench isolation region surrounds the plurality of fin structures and has a substantially uniform depth across the at least two spacings. The plurality of fin structures included a portion of each fin structure exposed to ion implantation, and the portion includes inert implanted species.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a prior art semiconductor device having fins of different pitches and a shallow trench isolation region having different heights as a result of the different pitches;

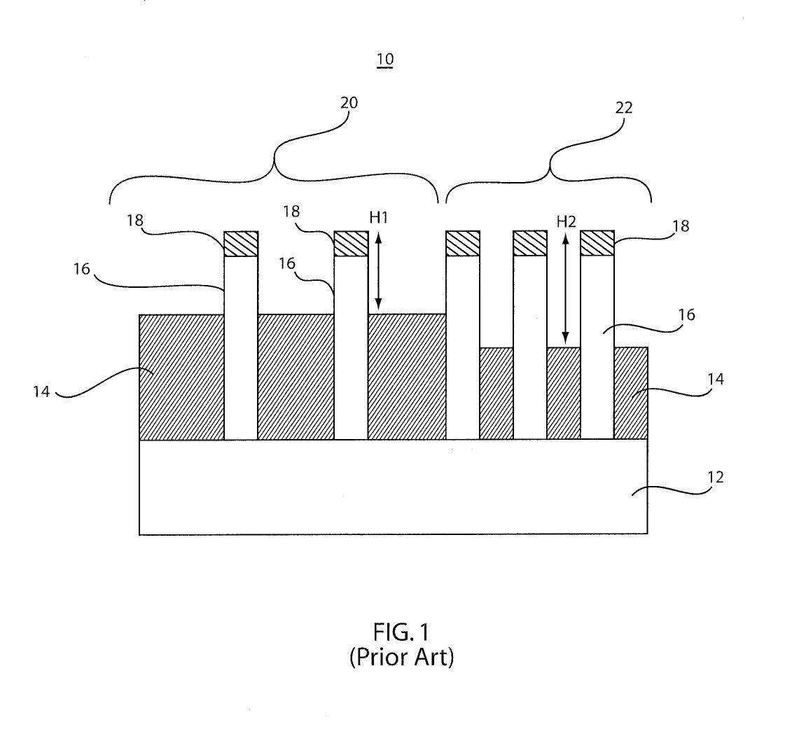

FIG. 2 is a cross-sectional view of a semiconductor structure in accordance with one embodiment having fins formed in a substrate;

FIG. 3 is a cross-sectional view of the semiconductor structure of FIG. 2 having a dielectric layer deposited and planarized in accordance with one embodiment;

FIG. 4 is a cross-sectional view of the semiconductor structure of FIG. 3 showing ion implantation of the dielectric layer (and fins) down to a depth in accordance with one embodiment;

FIG. 5 is a cross-sectional view of the semiconductor structure of FIG. 4 showing the ion implanted portion of the dielectric layer removed down to the depth, the fins including the implanted species in accordance with one embodiment;

FIG. 6 is a cross-sectional view of the semiconductor structure of FIG. 5 showing the structure annealed to repair possible damage in accordance with one embodiment; and

FIG. 7 is a flow diagram showing a method for fabricating a semiconductor device in accordance with the present principles.

### DETAILED DESCRIPTION OF PREFERRED EMBODIMENTS

In accordance with the present principles, devices and methods for uniformly recessing shallow trench isolation (STI) are provided. In one illustrative embodiment, the devices and methods are applied to bulk finFETs. Fins may be formed in a bulk semiconductor substrate. An STI dielectric is deposited and planarized. Inert species (e.g., Xenon or the like) are implanted into the STI dielectric to a predetermined depth as implemented by process parameters. The STI dielectric has a much higher etch rate than un-implanted dielectric. A wet etch may be employed to remove the implanted STI dielectric to uniformly recess the STI. Formation of the devices is completed by standard processing.

The flowchart and block diagrams in the Figures illustrate the architecture, functionality, and operation of possible implementations of devices and methods according to various embodiments of the present invention. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

It is also to be understood that the present invention will be described in terms of a given illustrative architecture having a bulk wafer; however, other architectures, structures, substrate materials and process features and steps may be varied within the scope of the present invention.

The devices as described herein may be part of a design for an integrated circuit chip. The chip design may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged faun. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

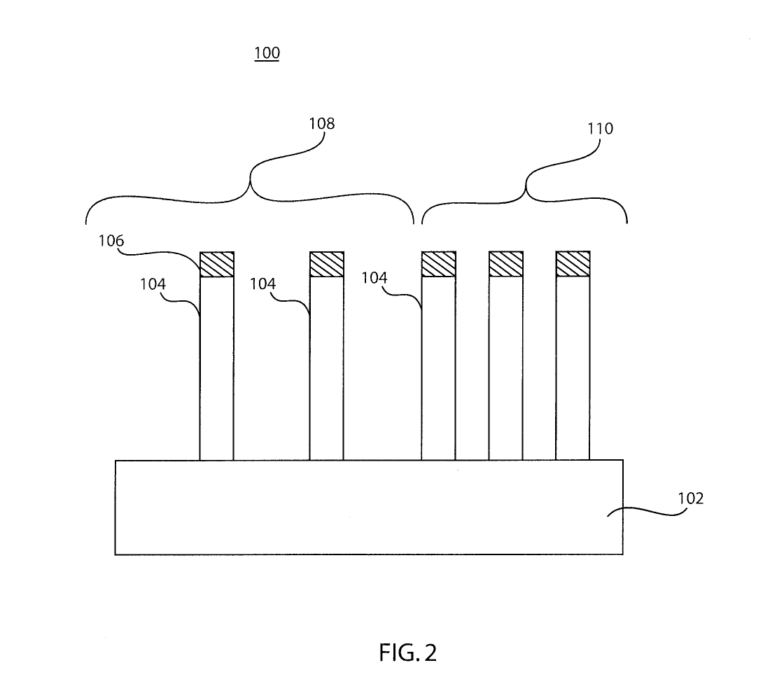

Referring now to the drawings in which like numerals represent the same or similar elements and initially to FIG. 2, a semiconductor structure 100 is illustratively shown. Structure 100 may include a thin semiconductor-on-insulator (SOI) or a bulk substrate 102 that may include Gallium Arsenide, monocrystalline silicon, Germanium, or any other material or combination of materials where the present principles may be applied. In some embodiments, the structure 100 further comprises other features or structures that are formed on or in the semiconductor substrate in previous process steps.

In one embodiment, the substrate 102 includes a thickness that is sufficient for forming fins or other structures 104 therein. Fins 104 are formed by depositing a cap layer 106 on a surface of the substrate 102, patterning the cap layer 106 and etching the substrate 102 to form the fins 104. The cap layer 106 may include silicon nitride, a silicon oxide or another of other suitable masking layer materials. Cap layer 106 is formed to a depth sufficient to achieve a needed depth in the substrate 102 for forming fins 104. Etching the substrate 102 to form fins 104, preferably includes a reactive ion etch or other anisotropic etching process.

The patterning of the fins 104 may include processes that provide sub-minimum feature size fin widths or larger widths (e.g., greater than or equal to the minimum feature size of a given lithographic technology employed for patterning the device 100). The patterning also includes providing areas with fins 104 or other structures with different pitches. For example, an area 108 includes fins 104 with a first pitch, and area 110 includes fins 104 with a second pitch. It should be understood that more than two different pitches may be employed and that the structures may include substrate features other than fins. Further, the fin structures include a plurality of different fin widths, or include fins and other structures etched into the substrate.

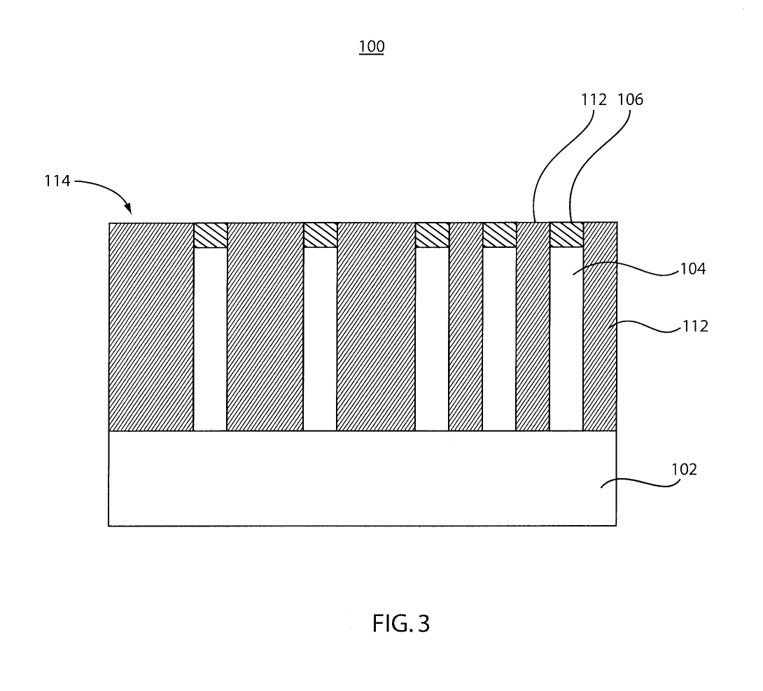

Referring to FIG. 3, an STI dielectric 112 is deposited on structure 100 and fills in gaps between fins 104 or other structures. Dielectric 112 may include an oxide, such as, a silicon oxide or other suitable dielectric materials. While nitrides, organic dielectrics or other materials may be employed, a silicon oxide is preferred. The dielectric 112 may be deposited using a chemical vapor deposition (CVD) process or other depositing process. The dielectric 112 may be etched or planarized down to a surface of the cap layer 106. For example, a chemical-mechanical polish (CMP) may be employed to planarize surface 114.

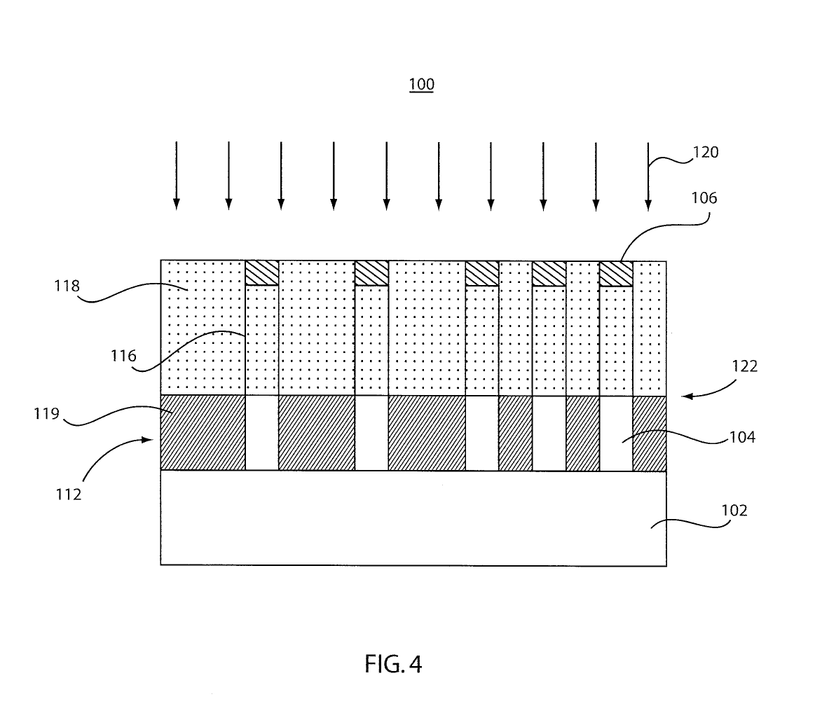

Referring to FIG. 4, structure 100 is subjected to an implanting process. The implanting process includes bombarding the structure 100 through a top surface with ions 120. The ions preferably include inert elements, such as, for example, noble gases (He, Ar, Ne, Xe, etc.), Ge, or other species. In one particularly useful embodiment, Xe ions are employed to implant the dielectric layer 112. In one example, the Xe is implanted with a dose of about 2×10¹⁴/cm². Other doses and species are also contemplated.

The implantation is carried out at a particular energy level to achieve a set depth 122 within the structure 100. The depth 122 may be adjusted according to implant species, material being implanted, energy of implantation, among other things. Material in region 118 above the depth 122 has been altered. Damage to dielectric 112 in region 118 has rendered this material to be etched faster than undamaged material (e.g., dielectric in region 119. In the example, described using Xe, a Xe-implanted oxide etches about 5× faster than un-implanted oxide.

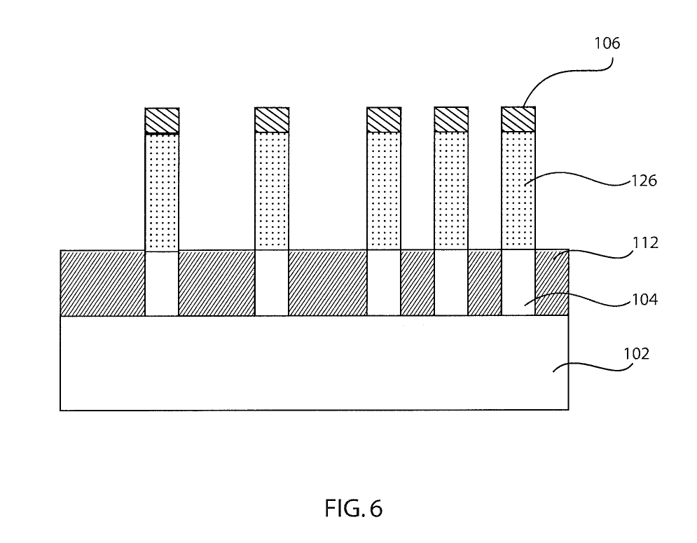

The implant species being inert has little or no effect on performance of any transistors (e.g., finFETs) or other devices formed using fin portions 116. In some instances the implantation process may provide a performance benefit to fins 104. In any event, any implant-related damage to the fin 104 in portion 116 may be recovered by performing a thermal anneal (see FIG. 6).

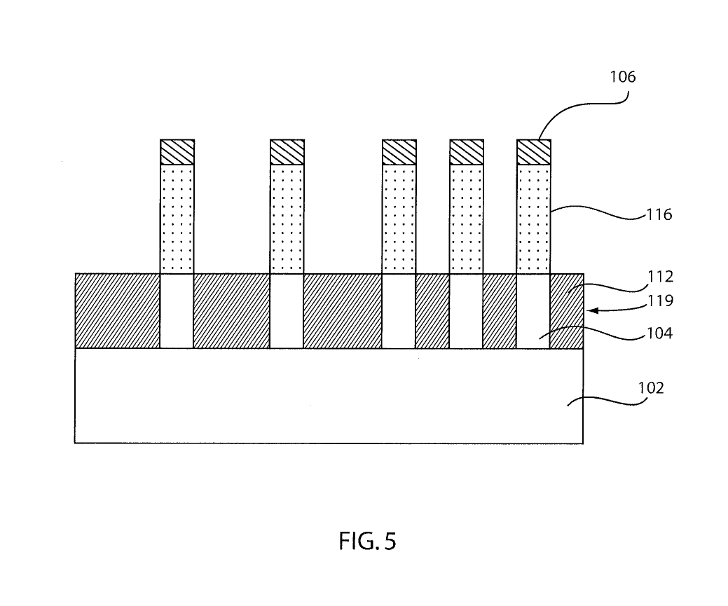

Referring to FIG. 5, an etch process is applied selectively to the remove the dielectric 112 from between fin portions 116. Despite the fins 104 having different pitches, the STI in region 119 is maintained at a substantially constant height corresponding to the implantation depth 122 selected. The etching process may include a wet etch, although any suitable etching process may be performed. Advantageously, the STI is recessed much more uniformly across the structure 100.

Referring to FIG. 6, a thermal anneal is optionally performed to recover any damage from the ion-implantation. The anneal process may vary in temperature and duration depending on the extent of the implantation damage. In one example, a thermal anneal includes a temperature of between about 200 degrees C. to about 800 degrees C., for between about 1 minute to about 10 minutes. It should be understood that the implantation species remain (residual species) in portions 126 after the anneal and may be employed to provide advantages in etching or other fabrication steps.

The processing of the finFETs or other structures can now continue in accordance with known methods. In the case of finFETs, this includes forming gate structures, source/drain regions, contacts, metal lines, etc.

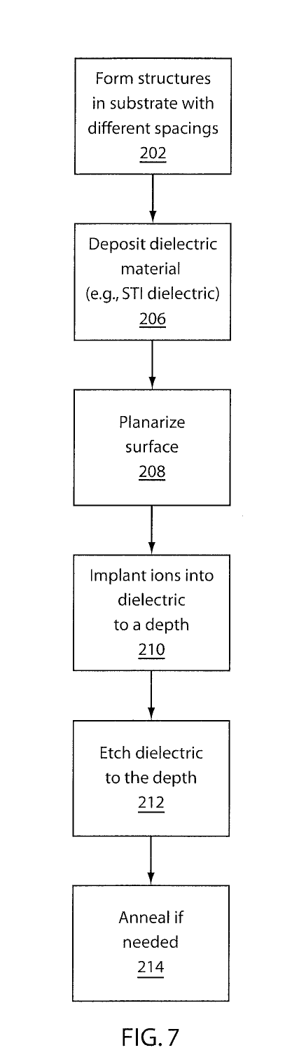

Referring to FIG. 7, a method for forming a semiconductor device is illustratively shown in accordance with one exemplary embodiment. In block 202, structures are formed in a semiconductor substrate. The structures are preferably formed by forming a mask (e.g., cap layer, photoresist, nitride spacers, etc.) on the substrate and etching the substrate using known etch processes. The structures have at least two different spacings (e.g., different pitches), but may include a greater number of different spacings. The structures may include fins, fins of different sizes or structures other than fins. In block 206, a dielectric material is deposited in the at least two different spacings. The dielectric material may include an oxide, although other materials may be employed. The dielectric material preferably includes a material suitable for the formation of shallow trench isolation regions. In block 208, the dielectric material is planarized, e.g., using a CMP process.

In block 210, ion species are implanted to a predetermined depth in the dielectric material. The species may include inert species, Ge or other elements. The implantation process provides a change to an etch rate of the dielectric material down to the depth. The ion species may also enter into the structures. In block 212, the dielectric material having the ion species is etched selective to the dielectric material below the depth such that a substantially uniform depth in the dielectric material is created across the at least two spacings. The dielectric material above the depth preferably has a greater etch rate than the dielectric material below the depth. In block 214, damage, if any, to the structures may be recovered by performing an anneal process.

Having described preferred embodiments of a device and method for a uniform STI recess (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method for forming a semiconductor device, comprising:
forming structures in a semiconductor substrate, the structures having at least two different spacings;
depositing a dielectric material in the at least two different spacings;
implanting ion species to a depth in the dielectric material to change an etch rate of the dielectric material down to the depth; and
etching the dielectric material having the ion species selective to the dielectric material below the depth such that a substantially uniform depth in the dielectric material is created across the at least two spacings.

2. The method as recited in claim 1, wherein forming structures includes forming fins and the at least two different spacings include regions of fins with different pitches.

3. The method as recited in claim 1, further comprising planarizing the dielectric material.

4. The method as recited in claim 1, wherein depositing a dielectric material includes depositing a silicon oxide dielectric material.

5. The method as recited in claim 1, wherein implanting ion species includes implanting an inert species.

6. The method as recited in claim 1, wherein implanting ion species to a depth in the dielectric material includes implanting the ion species into the structures, and further comprising recovering damage of the structures, if any, by performing an anneal process.

7. The method as recited in claim 1, wherein the dielectric material above the depth has a greater etch rate than the dielectric material below the depth.

8. A method for forming a semiconductor device, comprising:
forming fin structures in a semiconductor substrate, the structures having regions with at least two different spacings between the fins;
depositing a dielectric material in the at least two different spacings;
implanting an inert ion species to a depth in the dielectric material and in the fin structures to change an etch rate of the dielectric material down to the depth; and
etching the dielectric material having the ion species selective to the dielectric material below the depth to form a shallow trench isolation region having a substantially uniform depth in the dielectric material created across the at least two spacings.

9. The method as recited in claim 8, wherein the at least two different spacings include at least two different pitches.

10. The method as recited in claim 8, further comprising planarizing the dielectric material.

11. The method as recited in claim 8, wherein depositing a dielectric material includes depositing a silicon oxide dielectric material.

12. The method as recited in claim 8, wherein implanting ion species includes implanting an inert species.

13. The method as recited in claim 8, further comprising recovering damage of the fin structures, if any, by performing an anneal process.

14. The method as recited in claim 8, wherein the dielectric material above the depth has a greater etch rate than the dielectric material below the depth.

15. A semiconductor device, comprising:
a plurality of fin structures having at least two different spacings integrally formed in a semiconductor substrate; and
a shallow trench isolation region surrounding the plurality of fin structures and having a substantially uniform depth across the at least two spacings;
the plurality of fin structures including a portion of each fin structure exposed to ion implantation and the portion including inert implanted species.

16. The device as recited in claim 15, wherein the substrate includes a bulk substrate.

17. The device as recited in claim 15, wherein the inert implanted species include at least one of Ar, Ge and Xe.

18. The device as recited in claim 15, wherein the fin structures are integrated into fin field effect transistors.

19. The device as recited in claim 15, wherein the fin structures include a plurality of different fin widths.
